(19) United States
(12) Patent Application Publication
(10) Pub. No.: US 2022/0223815 A1
(43) Pub. Date: Jul. 14, 2022

(54) ORGANIC ELECTROLUMINESCENT DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Ke DING, Wuhan, Hubei (CN)

(21) Appl. No.: 16/613,406

(22) PCT Filed: Sep. 18, 2019
(86) PCT No.: PCT/CN2019/106521

§ 371 Date: Feb. 1, 2022

(30) Foreign Application Priority Data
Jun. 24, 2019 (CN) 201910548267.7

(51) Int. Cl. H01L 51/50

(52) U.S. Cl. CPC H01L 51/5076; H01L 51/506; H01L 51/5012; H01L 51/5092; H01L 51/5096

(57) ABSTRACT

An organic electroluminescent device includes an anode, a cathode disposed opposite to the anode, and a light emitting functional layer disposed between the anode and the cathode. The light emitting functional layer includes a light emitting layer and a PN junction layer disposed on a side of the light emitting layer, and when a positive charge is applied to the anode and a negative charge is applied to the cathode, the PN junction layer forms an open circuit, so that the cathode and the anode evenly inject carriers into the light emitting layer.

### FIELD OF INVENTION

The present invention relates to a field of display panel, and more particularly, to an organic electroluminescent device.

### DESCRIPTION OF PRIOR ART

The statements herein merely provide background information related to the present application and do not necessarily constitute prior art.

Organic light emitting diode (OLED) devices have self-illumination, ultra-thin, low power consumption, and high contrast, and they can be applied to flexible displays. Thus, OLED devices have been focused and studied in the display industry.

Most of the OLED devices used in flat panel displays are top-emitting OLEDs (TEOLEDs). When electrons and holes in TEOLEDs have great different transmission capabilities, carriers, including electrons and holes, are injected at greatly different rates, so that an exciton recombination region of the device deviates from the light emitting layer and is close to a side of carriers having a lower transmission capability, and the recombination region is narrow, which is disadvantageous to the continuous improvement of devices lifetime and efficiency. In addition, the P-i-N-type OLED structure can effectively reduce device driving voltage and improve device performance. The P-type doped hole transport layer and the N-type doped electron transport layer are disposed on the anode side and cathode side, respectively, and the middle layer is an undoped light emitting layer or a combined layer of the light emitting layer and exciton barrier layer, and the exciton is constituted of electrons and holes. Studies have shown that cathode deposited in the vapor deposition process causes self-doping of the N-doped electron transport layer and destroys the performance of the N-doped electron transport layer, and the self-doping effect varies with the type of vapor deposited metal, the evaporation environment, the evaporation rate, and the like, which causes unstable device performance.

Accordingly, the OLED devices have technical problems of carrier injection unbalance, device lifetime, and work efficiency caused by self-doping of the N-doped electron transport layer during vapor deposition of the cathode. The contact surface of the P-type doped layer and the N-type doped layer 10 forms a PN junction

### SUMMARY OF INVENTION

An organic electroluminescent device is provided to solve technical problems of carrier injection unbalance, device lifetime, and work efficiency caused by self-doping of the N-doped electron transport layer during vapor deposition of the cathode by disposing PN junction layer having a rectifying property in the light emitting layer.

An organic electroluminescent device includes an anode, a cathode disposed opposite to the anode, and a light emitting functional layer disposed between the anode and the cathode. The light emitting functional layer includes a light emitting layer and a PN junction layer disposed on a side of the light emitting layer, and when a positive charge is applied to the anode and a negative charge is applied to the cathode, the PN junction layer forms an open circuit, so that the cathode and the anode evenly inject carriers into the light emitting layer.

In one embodiment, the PN junction layer is disposed on the side of the light emitting layer close to the cathode, and when the positive charge is applied to the anode and the negative charge is applied to the cathode, the PN junction layer forms an open circuit to suppress that the cathode injects electrons into the light emitting layer, so that the cathode and the anode evenly inject the carriers into the light emitting layer.

In one embodiment, the PN junction layer includes a P-type doped layer and an N-type doped layer. The P-type doped layer is stacked on the N-type doped layer, and the P-type doped layer is disposed between the N-type doped layer and the cathode. The light emitting functional layer further includes an electron transport layer, and the electron transport layer is disposed between the cathode and the P-type doped layer, or the electron transport layer is disposed between the light emitting layer and the N-type doped layer.

In one embodiment, the light emitting functional layer further includes a hole transport layer disposed on a side of the light emitting layer close to the anode, and the hole transport layer includes a P-type doped hole transport layer or an undoped hole transport layer.

In one embodiment, the PN junction layer includes a P-type doped layer and an N-type doped layer. The P-type doped layer is stacked on the N-type doped layer, and the P-type doped layer is disposed between the N-type doped layer and the cathode. The N-type doped layer comprises an N-type doped electron transport layer.

In one embodiment, the light emitting functional layer further includes a hole transport layer disposed on a side of the light emitting layer close to the anode, and the hole transport layer comprises a P-type doped hole transport layer or an undoped hole transport layer.

In one embodiment, the PN junction layer is disposed on the side of the light emitting layer close to the cathode, and when positive charge is applied to the anode and the negative charge is applied to the cathode, the PN junction layer forms the open circuit to suppress that the anode injects holes into the light emitting layer, so that the cathode and the anode evenly inject the carriers into the light emitting layer.

In one embodiment, the PN junction layer includes a P-type doped layer and an N-type doped layer. The P-type doped layer is stacked on the N-type doped layer, and the N-type doped layer is disposed between the P-type doped layer and the anode. The light emitting functional layer further includes a hole transport layer, and the hole transport layer is disposed between the anode and the N-type doped layer, or the hole transport layer is disposed between the light emitting layer and the P-type doped layer.

In one embodiment, the light emitting functional layer further includes an electron transport layer disposed on a side of the light emitting layer close to the cathode, and the electron transport layer comprises an N-type doped electron transport layer or an undoped electron transport layer.

In one embodiment, the PN junction layer includes a P-type doped layer and an N-type doped layer. The P-type doped layer is stacked on the N-type doped layer, and the N-type doped layer is disposed between the P-type doped layer and the anode. The P-type doped layer includes a P-type doped hole transport layer or a P-type doped hole injection layer.

In one embodiment, the light emitting functional layer further includes an electron transport layer disposed on a side of the light emitting layer close to the cathode, and the electron transport layer comprises an N-type doped electron transport layer or an undoped electron transport layer.

In one embodiment, the light emitting functional layer further includes an injection control layer, and material of the injection control layer includes an electron blocking material, a hole blocking material, or an exciton blocking material, and the injection control layer is disposed between on the light emitting layer and the PN junction layer, or the injection control layer is disposed on a side of the light emitting layer away from the PN junction layer.

In one embodiment, the organic electroluminescent device further includes a coupling light emitting layer disposed on a side of the cathode away from the anode.

In one embodiment, the organic electroluminescent device further includes an electron injection layer disposed on the cathode close to a side of the light emitting functional layer.

In one embodiment, the PN junction layer includes small organic molecule materials.

An organic electroluminescent device includes an anode, a cathode disposed opposite to the anode, and a light emitting functional layer disposed between the anode and the cathode. The light emitting functional layer includes a light emitting layer, a PN junction layer disposed on a side of the light emitting layer close to the anode, and the PN junction layer comprises a P-type doped layer and an N-type doped layer. The P-type doped layer is stacked on the N-type doped layer, and the P-type doped layer is disposed between the N-type doped layer and the cathode. The N-type doped layer comprises a N-type doped electron transport layer. When a positive charge is applied to the anode and a negative charge is applied to the cathode, the PN junction layer forms an open circuit, so that the cathode and the anode evenly inject carriers into the light emitting layer.

The PN junction layer is disposed in the light emitting layer. The PN junction layer has a rectifying property. When a positive charge is applied to the anode and a negative charge is applied to the cathode, the PN junction layer forms an open circuit, which can suppress excessive injection of carriers (electrons or holes) having a fast migration rate, so that the cathode and the anode evenly inject carriers into the light emitting layer, which is advantageous to service life and work efficiency of the organic electroluminescent device. The PN junction layer 6 includes a P-type doped layer 9 and an N-type doped layer 10 stacked on the P-type doped layer having a rectifying property. The P-type doped layer is disposed close to the cathode and the N-type doped is disposed close to the anode. When a positive charge is applied to the anode and a negative charge is applied to the cathode, the P-type doped layer is connected to negative electrode and the N-type doped layer is connected to the positive electrode, and the PN junction forms an open circuit, so the carriers transport close to the PN junction layer is achieved by the tunneling effect occurred at the PN junction, which can suppress excessive injection of carriers. Therefore, the cathode and the anode evenly inject carriers into the light emitting layer. When the PN junction layer is disposed between the cathode and the light emitting layer, the N-type doped layer includes N-type doped electron transport layer, and the P-type doped layer is disposed between the N-type doped electron transport layer and the cathode, which can effectively suppress self-doping of N-type doped electron transport layer in the metal cathode vapor deposition process. Therefore, service life and work efficiency of the organic electroluminescent device are improved.

### BRIEF DESCRIPTION OF DRAWINGS

In order to more clearly illustrate the technical solutions in the embodiments of the present invention, the drawings used in the description of the embodiments will be briefly described below. It is obvious that the drawings in the following description are only some embodiments of the present invention. Other drawings can also be obtained from those skilled persons in the art based on these drawings without paying any creative effort.

FIG. 1 is a schematic view of an organic electroluminescent device according to one embodiment of the present invention.

FIG. 2 is a schematic view of an organic electroluminescent device according to another embodiment of the present invention.

FIG. 3 is a schematic view of an organic electroluminescent device according to another embodiment of the present invention.

FIG. 4 is a schematic view of an organic electroluminescent device according to another embodiment of the present invention.

FIG. 5 is a schematic view of an organic electroluminescent device according to another embodiment of the present invention.

FIG. 6 is a schematic view of an organic electroluminescent device according to another embodiment of the present invention.

FIG. 7 is a schematic view of an organic electroluminescent device according to another embodiment of the present invention.

FIG. 8 is a schematic view of an organic electroluminescent device according to another embodiment of the present invention.

FIG. 9 is a schematic view of an organic electroluminescent device according to another embodiment of the present invention.

FIG. 10 is a schematic view of an organic electroluminescent device according to another embodiment of the present invention.

### DETAILED DESCRIPTION OF PREFERRED EMBODIMENTS

The specific structural and functional details disclosed herein are merely representative and are for purposes of describing exemplary embodiments of the present invention. The present invention, however, may be implemented in many alternative ways and should not be construed as being limited to the embodiments set forth herein.

In the description of the present invention, it should be understood that the terms including “center,” “lateral,” “upper,” “lower,” “left,” “right,” “vertical,” “horizontal,” “top,” “bottom,” “inside,” and “outside” are based on the orientation or positional relationship shown in the drawings, and the terms are merely for convenience of description of the present invention and simplified description, and do not indicate or imply the indicated device or the components must have a specific orientation, specific orientation structure, and operation, and thus they are not to be construed as limiting. Moreover, the terms “first” and “second” are only used for describing purposes and are not to be understood as indicating or implying a relative importance or indicating the number of technical features. Thus, features defining “first” and “second” may include one or more of the features either explicitly or implicitly. In the description of the present invention, “a plurality” means two or more unless otherwise stated. In addition, the term “include” and its variations are intended to have others not described in the specification.

In the description of the present invention, it should be noted that the terms “installation,” “link,” and “connection” are to be understood broadly unless otherwise specifically defined. For example, it may be a fixed connection, a detachable connection, or an integral connection; it may be a mechanical connection or an electrical connection; it may be direct connection or indirectly connected through an intermediate medium, and It may be the internal connection between two components. The specific meanings of the above terms in the present invention can be understood in the specific circumstances for those skilled persons in the art.

The terminology used herein is for the purpose of describing the particular embodiments. The singular terms “a” and “an” intend to include a plurality of subjects. It is also to be understood that the terms “comprise” and/or “include” used herein are intended to mean the existence of the recited features, integers, steps, operations, units, and/or components, and do not exclude the existence or addition of one or more other features, integers, steps, operations, units, components, and/or combinations thereof.

The present application will be further described below with the accompanying drawings and embodiments.

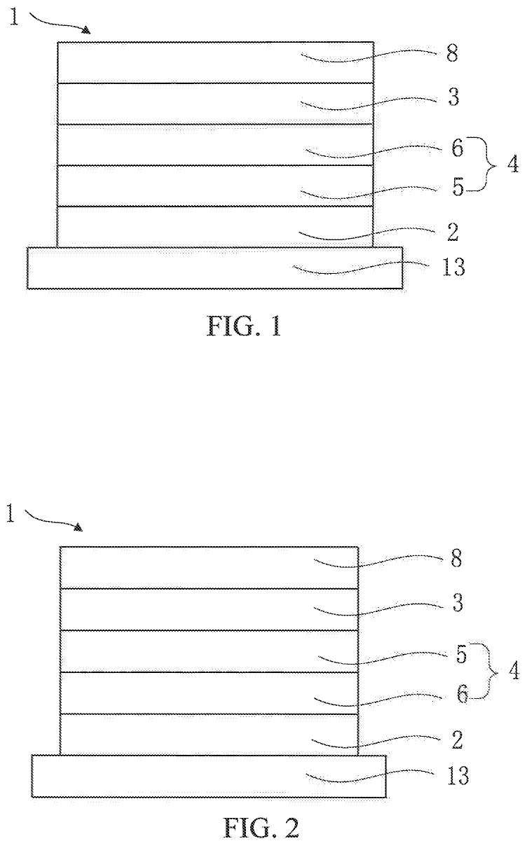

Referring to FIG. 1 and FIG. 2, an organic electroluminescent device 1 includes an anode 2, a cathode 3 disposed opposite to the anode 2, and a light emitting functional layer 4 disposed between the anode 2 and the cathode 3. the light emitting functional layer 4 includes a light emitting layer 5 and a PN junction layer 6 disposed on a side of the light emitting layer 5, and when a positive charge is applied to the anode 2 and a negative charge is applied to the cathode 3, the PN junction layer 6 forms an open circuit, so that the cathode 3 and the anode 2 evenly inject carriers into the light emitting layer 5.

Specifically, the organic electroluminescent device 1 further includes a substrate 13, and the anode 2 is disposed on the substrate 13.

Specifically, the light emitting layer 5 includes a host-guest dopant material, and the anode 2 includes, but is not limited to, a high work function metal or a metal oxide. The cathode 3 is transparence, and the cathode 3 includes, but is not limited to, a metal or a metal alloy. The carriers include electrons, holes or excitons. The cathode 3 supplies electrons, and the electrons migrate from the cathode 3 to the light emitting layer 5. The anode 2 supplies holes, and the holes migrate from the anode 2 to the light emitting layer 5. The electrons injected by the cathode 3 and the holes injected by the anode 2 are combined in the light emitting layer 5 to form electron-hole pairs (i.e., excitons) at a binding energy level, and excitons are de-excited to emit photons, and visible light is generated in the light emitting layer 5.

When the electron injection rate and the hole injection rate are unbalanced, the exciton recombination region will be close to a side with a slower exciton injection rate, so that the exciton recombination region deviates from the light emitting layer 5, and the recombination region is narrow, which is disadvantageous to service life and work efficiency of the organic electroluminescent device 1.

Specifically, the PN junction layer 6 includes a PN junction, which is a transition region near the interface between the P-type semiconductor and the N-type semiconductor. The PN junction has a rectifying property, that is, when the P-type semiconductor is connected to the positive electrode and the N-type semiconductor is connected to the negative electrode, the PN junction is turned on. When the P-type semiconductor is connected to the negative electrode and the N-type semiconductor is connected to the positive electrode, the PN junction is not turned on and carriers are not transferred. The PN junction layer 6 is disposed on one side of the light emitting layer 5, it may be disposed on the side of the light emitting layer 5 close to the cathode 3 or on the side of the light emitting layer 5 close to the anode 2. The position of the PN junction layer 6 is determined by the electron migration rate and hole migration rate in the organic electroluminescent device 1. As shown in FIG. 1, when the electron migration rate is greater than the hole migration rate, the PN junction layer 6 is disposed on the side of the light emitting layer 5 close to the anode 3. As shown in FIG. 2, when the hole migration rate is greater than the electron migration rate, the PN junction layer 6 is disposed on the side of the light emitting layer 5 close to the cathode 3.

The PN junction layer 6 has a rectifying property by disposing PN junction layer 6 in the light emitting functional layer 4. When a positive charge is applied to the anode 2 and a negative charge is applied to the cathode 3, the PN junction layer 6 forms an open circuit, so the carriers transport close to the PN junction layer 6 is achieved by the tunneling effect occurred at the PN junction, which can suppress excessive injection of carriers having a fast migration rate. Therefore, the cathode 3 and the anode 2 evenly inject carriers into the light emitting layer 5, which is advantageous to service life and work efficiency of the organic electroluminescent device 1.

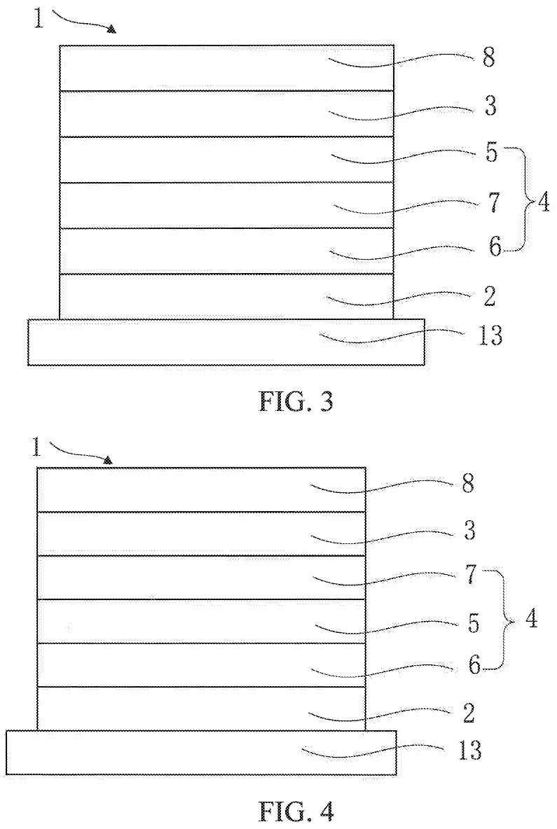

Referring to FIG. 3 and FIG. 4, the light emitting layer functional layer 4 further an injection control layer 7, and material of the injection control layer 7 includes an electron blocking material, a hole blocking material, or an exciton blocking material. As shown in FIG. 3, the injection control layer 7 is disposed between on the light emitting layer 5 and the PN junction layer 6, or as shown in FIG. 4, the injection control layer 7 is disposed on a side of the light emitting layer 5 away from the PN junction layer 6.

The injection control layer 7 helps the PN junction layer 6 to control the injection balance of carriers in the organic electroluminescent device 1. The injection control layer 7 can block the migration of electrons, holes, or excitons. The material of the injection control layer 7 is determined by the position of the injection control layer 7 and the migration rate of the carriers. When the injection control layer 7 is disposed between the light emitting layer 5 and the PN junction layer 6, the material of the injection control layer 7 includes an electron blocking material, a hole blocking material, or an exciton blocking material. When the injection control layer 7 is disposed on a side of the light emitting layer 5 away from the PN junction layer 6, the injection control layer 7 includes a barrier material having a faster carrier migration rate, and the ultimate purpose is that electrons and holes injected into the light emitting layer 5 are balanced, and exciton reverse energy transfer occurred at the light emitting layer 5, which results exciton quenching phenomenon, can be avoided. Therefore, the working efficiency of the organic electroluminescent device 1 is improved.

Referring to FIG. 1 to FIG. 4, the organic electroluminescent device further includes a coupling light emitting layer 8 disposed on a side of the cathode 3 away from the anode 2. The coupling light emitting layer 8 is used to increase the light emitting efficiency and reduce the light emitting loss of the organic electroluminescent device 1.

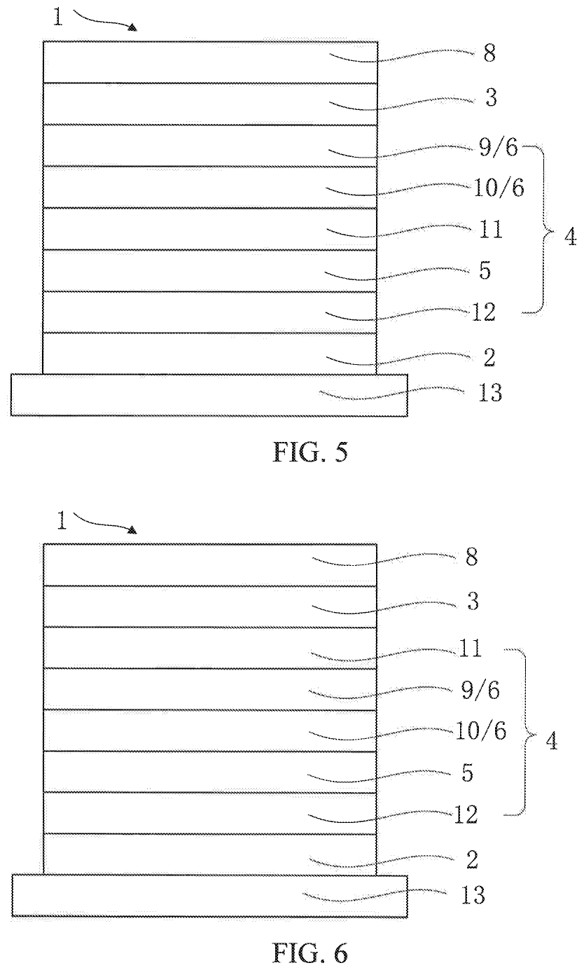

Referring to FIG. 5 and FIG. 6, an organic electroluminescent device 1 is provided, and the difference is that the PN junction layer 6 is disposed on a side of the light emitting layer 5 close to the cathode 3, and when a positive charge is applied to the anode 2 and a negative charge is applied to the cathode 3, the PN junction layer 6 forms an open circuit to suppress the cathode 3 injecting electrons into the light emitting layer 5, so that the cathode 3 and the anode 2 evenly inject carriers into the light emitting layer 5.

Specifically, the electron migration rate is greater than the hole migration rate. For example, most blue host (BH) materials are electron hosts, and the electron transport ability is better than the hole transport ability. When the organic electroluminescent device 1 includes the host materials, the exciton recombination region of the organic electroluminescent device 1 is close to the anode 2 side, and and the recombination region is narrow, which is disadvantageous to the service life and work efficiency of the organic electroluminescent device 1. When a positive charge is applied to the anode 2 and a negative charge is applied to the cathode 3, the PN junction layer 6 forms an open circuit, and excessive injection of electrons can be suppressed, so that the cathode 3 and the anode 2 evenly inject electrons and holes into the light emitting layer 5, which is advantageous to service life and work efficiency of the organic electroluminescent device 1.

The PN junction layer 6 includes a P-type doped layer 9 and an N-type doped layer 10. The P-type doped layer 9 is stacked on the N-type doped layer 10, and the P-type doped layer 9 is disposed between the N-type doped layer 10 and the cathode 3. The light emitting functional layer 4 further includes an electron transport layer 11. As shown in FIG. 5, the electron transport layer 11 is disposed between the light emitting layer 5 and the N-type doped layer 10, or the electron transport layer 11 is disposed between the cathode 3 and the P-type doped layer 9 as shown in FIG. 6.

Specifically, the P-type doped layer 9 corresponds to a P-type semiconductor and the N-type doped layer 10 corresponds to an N-type semiconductor. The contact surface of the P-type doped layer 9 and the N-type doped layer 10 forms a PN junction having a rectifying property. The P-type doped layer 9 and the N-type doped layer 10 include, but are not limited to, organic small molecule materials, and the electron transport layer 11 includes, but is not limited to, organic small molecule materials.

Specifically, an electron injection layer (not shown in the figure) is disposed on the side of the cathode 3 close to the light emitting layer 5. The electron injection layer includes, but is not limited to, metal materials. If the electron transport layer 11 has the functions of electron injection and electron transport, it does not dispose the electron injection layer.

The contact surface of the P-type doped layer 9 and the N-type doped layer 10 forms a PN junction having rectifying properties. The P-type doped layer 9 is disposed close to the cathode 3, and when a positive charge is applied to the anode 2 and a negative charge is applied to the cathode 3, the P-type doped layer 9 is connected to negative electrode (cathode 3) and the N-type doped layer 10 is connected to the positive electrode (anode 2), and the PN junction forms an open circuit, so that electron transport is achieved by the tunneling effect occurred at the PN junction. Generally, electron transport and electron injection are weakened to suppress excessive injection of electrons, so that the cathode 3 and the anode 2 evenly inject electrons and holes into the light emitting layer 5.

The light emitting functional layer 4 further includes a hole transport layer 12 disposed on a side of the light emitting layer 5 close to the anode 2, and the hole transport layer 12 includes a P-type doped hole transport layer or an undoped hole transport layer.

Specifically, the hole transport layer 12 includes, but is not limited to, small organic molecule materials.

The hole transport layer 12 reduces hole injection barrier and improves hole injection efficiency. The hole transport layer 12 includes a P-type doped hole transport layer or an undoped hole transport layer. The P-type doped hole transport layer has a better effect of injecting holes than the undoped hole transport layer, and thus the driving voltage required for hole injection is reduced and the performance of the organic electroluminescent device 1 is improved, and the hole transport layer 12 is, but not limited to, doped or not.

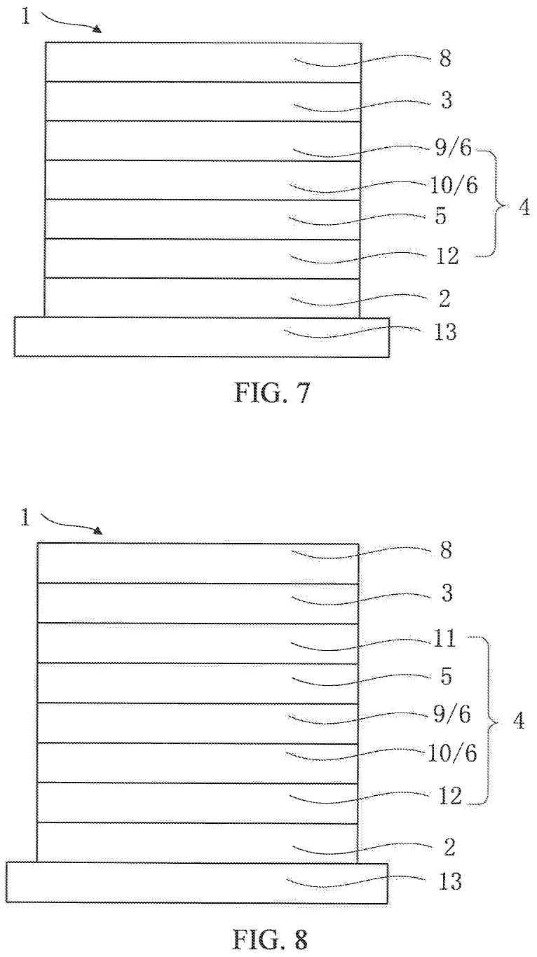

Referring to FIG. 7, an organic electroluminescent device 1 is further provided, and the difference is that the PN junction layer 6 includes a P-type doped layer 9 and an N-type doped layer 10. The P-type doped layer 9 is stacked on the N-type doped layer 10, and the P-type doped layer 9 is disposed between the N-type doped layer 10 and the cathode 3. The N-type doped layer 10 includes a N-type doped electron transport layer.

The N-type doped layer 10 is composed of the PN junction layer 6, and is also an electron transport layer of the organic electroluminescent device 1. Specifically, the N-type doped layer 10 is an N-type doped electron transport layer, which achieves the PN junction and electron transport. In addition, the N-type doped electron transport layer can be self-doped during evaporating the cathode 3, and thus the performance of the N-type doped electron transport layer is damaged, but it does not cause the P-type doped layer to be self-doped. Therefore, the P-type doped layer 9 is disposed between the N-type doped layer 10 and the cathode 3 to avoid self-doping of the N-type doped electron transport layer during the evaporating the cathode 3, thereby improving service life and work efficiency of the organic electroluminescent device 1.

The light emitting functional layer 4 further includes a hole transport layer 12 disposed on a side of the light emitting layer 5 close to the anode 2, and the hole transport layer 12 includes a P-type doped hole transport layer or an undoped hole transport layer.

The hole transport layer 12 reduces hole injection barrier and improves hole injection efficiency. The hole transport layer 12 includes a P-type doped hole transport layer or an undoped hole transport layer. The P-type doped transport layer has a better effect of injecting holes than the undoped hole transport layer, and the hole transport layer 12 is, but not limited to, doped or not. Furthermore, when the hole transport layer 12 is a P-type doped hole transport layer, the P-type doped hole transport layer, the light emitting layer 5, the N-type doped electron transport layer, and the P-type doped layer 9 form a P-i-N-P structure. Thus, the driving voltage of the organic electroluminescent device 1 is effectively reduced and the performance of the organic electroluminescent device 1 is improved.

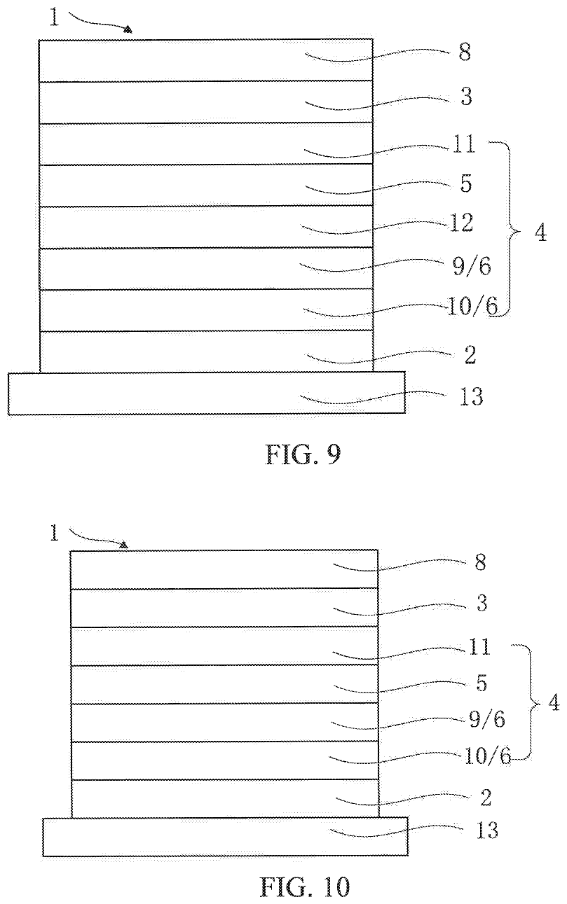

Referring to FIG. 8 and FIG. 9, an organic electroluminescent device 1 is further provided, and the difference is that the PN junction layer 6 is disposed on a side of the light emitting layer 5 close to the anode 2, and when a positive charge is applied to the anode 2 and a negative charge is applied to the cathode 3, the PN junction layer 6 forms an open circuit to suppress the anode 2 injecting electrons into the light emitting layer 5, so that the cathode 3 and the anode 2 evenly inject carriers into the light emitting layer 5.

Specifically, the hole migration rate is greater than the electron migration rate. The exciton recombination region of the organic electroluminescent device 1 is close to the cathode 3 side, and the recombination region is narrow, which is disadvantageous to the service life and work efficiency of the organic electroluminescent device 1. When a positive charge is applied to the anode 2 and a negative charge is applied to the cathode 3, the PN junction layer 6 forms an open circuit, and excessive injection of holes can be suppressed, so that the cathode 3 and the anode 2 evenly inject electrons and holes into the light emitting layer 5, which is advantageous to service life and work efficiency of the organic electroluminescent device 1.

The PN junction layer 6 includes a P-type doped layer 9 and an N-type doped layer 10. The P-type doped layer 9 is stacked on the N-type doped layer 10, and the N-type doped layer 10 is disposed between the P-type doped layer 9 and the anode 2. The light emitting functional layer 4 further includes a hole transport layer 12. As shown in FIG. 8, the hole transport layer 12 is disposed between the anode 2 and the N-type doped layer 10, or the hole transport layer 12 is disposed between the light emitting layer 5 and the P-type doped layer 9 as shown in FIG. 9.

Specifically, the P-type doped layer 9 corresponds to a P-type semiconductor and the N-type doped layer 10 corresponds to an N-type semiconductor. The contact surface of the N-type doped layer 9 and the N-type doped layer 10 forms a PN junction having rectifying properties. The P-type doped layer 9 and the N-type doped layer 10 include, but are not limited to, organic small molecule materials, and the hole transport layer 12 includes, but is not limited to, small organic small molecule materials.

Specifically, a hole injection layer (not shown in the figure) is disposed on the side of the anode 3 close to the light emitting layer 5. The hole injection layer includes, but is not limited to, small organic small molecule materials. If the hole transport layer 12 has the functions of hole injection and hole transport, it does not dispose the hole injection layer.

The contact surface of the P-type doped layer 9 and the N-type doped layer 10 forms a PN junction having rectifying properties. The N-type doped layer 10 is disposed close to the anode 2, and when a positive charge is applied to the anode 2 and a negative charge is applied to the cathode 3 is applied to, the P-type doped layer 9 is connected to negative electrode (cathode 3) and the N-type doped layer 10 is connected to the positive electrode (anode 2), and the PN junction forms an open circuit to suppress injecting excessive holes, so that the cathode 3 and the anode 2 evenly inject electrons and holes into the light emitting layer 5.

The light emitting functional layer 4 further includes a electron transport layer 11 disposed on a side of the light emitting layer 5 close to the cathode 3, and the electron transport layer 11 includes a N-type doped electron transport layer or an undoped electron transport layer.

Specifically, the electron transport layer 11 includes, but is not limited to, small organic molecule materials.

The electron transport layer 11 reduces electron injection barrier and improves electron injection efficiency. The electron transport layer 11 includes a N-type doped electron transport layer or an undoped electron transport layer. The N-type doped electron transport layer has a better effect of injecting electrons than the undoped electron transport layer, and thus the driving voltage required for electron injection is reduced and the performance of the organic electroluminescent device 1 is improved, and the electron transport layer 11 is, but not limited to, doped or not.

Referring to FIG. 10, an organic electroluminescent device 1 is further provided, and the difference is that the PN junction layer 6 includes a P-type doped layer 9 and an N-type doped layer 10. The P-type doped layer 9 is stacked on the N-type doped layer 10, and the N-type doped layer 10 is disposed between the P-type doped layer 9 and the anode 2. The P-type doped layer 9 includes a P-type doped hole transport layer or P-type doped hole injection layer.

The P-type doped layer 9 is composed of the PN junction layer 6, and is also a hole transport layer or a hole injection layer of the organic electroluminescent device 1. Specifically, the P-type doped layer 9 is a P-type doped hole transport layer or a P-type doped hole injection layer, which achieves the PN junction and electron transport. In addition, when the P-type doped layer 9 is a P-type doped hole transport layer, a hole injection layer is disposed between the N-type doped layer 10 and the anode 2. If the P-type hole transport layer has the functions of hole injection and hole transport, it does not need to dispose the hole injection layer between the N-type doped layer 10 and the anode 2. When the P-type doped layer 9 is a P-type doped hole injection layer, a hole transport layer is also disposed between the P-type hole injection layer and the light emitting layer 5 to improve hole injection efficiency of the PN junction.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. An organic electroluminescent device, comprising:
an anode;
a cathode disposed opposite to the anode; and
a light emitting functional layer disposed between the anode and the cathode;
wherein the light emitting functional layer comprises a light emitting layer and a PN junction layer disposed on a side of the light emitting layer, and when a positive charge is applied to the anode and a negative charge is applied to the cathode, the PN junction layer forms an open circuit, so that the cathode and the anode evenly inject carriers into the light emitting layer.

2. The organic electroluminescent device according to claim 1, wherein the PN junction layer is disposed on a side of the light emitting layer close to the cathode, and when a positive charge is applied to the anode and a negative charge is applied to the cathode, the PN junction layer forms an open circuit to suppress that the cathode injects electrons into the light emitting layer, so that the cathode and the anode evenly inject the carriers into the light emitting layer.

3. The organic electroluminescent device according to claim 2, wherein the PN junction layer comprises a P-type doped layer and an N-type doped layer;
wherein the P-type doped layer is stacked on the N-type doped layer, and the P-type doped layer is disposed between the N-type doped layer and the cathode; and
wherein the light emitting functional layer further comprises an electron transport layer, and the electron transport layer is disposed between the cathode and the P-type doped layer, or the electron transport layer is disposed between the light emitting layer and the N-type doped layer.

4. The organic electroluminescent device according to claim 3, wherein the light emitting functional layer further comprises a hole transport layer disposed on a side of the light emitting layer close to the anode, and the hole transport layer comprises a P-type doped hole transport layer or an undoped hole transport layer.

5. The organic electroluminescent device according to claim 2, wherein the PN junction layer comprises a P-type doped layer and an N-type doped layer;
wherein the P-type doped layer is stacked on the N-type doped layer, and the P-type doped layer is disposed between the N-type doped layer and the cathode; and
wherein the N-type doped layer comprises an N-type doped electron transport layer.

6. The organic electroluminescent device according to claim 5, wherein the light emitting functional layer further comprises a hole transport layer disposed on a side of the light emitting layer close to the anode, and the hole transport layer comprises a P-type doped hole transport layer or an undoped hole transport layer.

7. The organic electroluminescent device according to claim 1, wherein the PN junction layer is disposed on the side of the light emitting layer close to the cathode, and when the positive charge is applied to the anode and the cathode is applied to the negative charge, the PN junction layer forms the open circuit to suppress that the anode injects holes into the light emitting layer, so that the cathode and the anode evenly inject the carriers into the light emitting layer.

8. The organic electroluminescent device according to claim 7, wherein the PN junction layer comprises a P-type doped layer and an N-type doped layer;
wherein the P-type doped layer is stacked on the N-type doped layer, and the N-type doped layer is disposed between the P-type doped layer and the anode; and
wherein the light emitting functional layer further comprises a hole transport layer, and the hole transport layer is disposed between the anode and the N-type doped layer, or the hole transport layer is disposed between the light emitting layer and the P-type doped layer.

9. The organic electroluminescent device according to claim 8, wherein the light emitting functional layer further comprises an electron transport layer disposed on a side of the light emitting layer close to the cathode, and the electron transport layer comprises an N-type doped electron transport layer or an undoped electron transport layer.

10. The organic electroluminescent device according to claim 7, wherein the PN junction layer comprises a P-type doped layer and an N-type doped layer;
wherein the P-type doped layer is stacked on the N-type doped layer, and the N-type doped layer is disposed between the P-type doped layer and the anode; and
wherein the P-type doped layer comprises a P-type doped hole transport layer or a P-type doped hole injection layer.

11. The organic electroluminescent device according to claim 10, wherein the light emitting functional layer further comprises an electron transport layer disposed on a side of the light emitting layer close to the cathode, and the electron transport layer comprises an N-type doped electron transport layer or an undoped electron transport layer.

12. The organic electroluminescent device according to claim 1, wherein the light emitting functional layer further comprises an injection control layer, and material of the injection control layer comprises an electron blocking material, a hole blocking material, or an exciton blocking material, and the injection control layer is disposed between on the light emitting layer and the PN junction layer, or the injection control layer is disposed on a side of the light emitting layer away from the PN junction layer.

13. The organic electroluminescent device according to claim 1, the organic electroluminescent device further comprises a coupling light emitting layer disposed on a side of the cathode away from the anode.

14. The organic electroluminescent device according to claim 1, the organic electroluminescent device further comprises an electron injection layer disposed on the cathode close to a side of the light emitting functional layer.

15. The organic electroluminescent device according to claim 1, the PN junction layer comprises small organic molecule materials.

16. An organic electroluminescent device, comprising:
an anode;
a cathode disposed opposite to the anode; and
a light emitting functional layer disposed between the anode and the cathode;
wherein the light emitting functional layer comprises a light emitting layer, a PN junction layer disposed on a side of the light emitting layer close to the anode, and the PN junction layer comprises a P-type doped layer and an N-type doped layer;
wherein the P-type doped layer is stacked on the N-type doped layer, and the P-type doped layer is disposed between the N-type doped layer and the cathode;
wherein the N-type doped layer comprises a N-type doped electron transport layer; and
wherein when a positive charge is applied to the anode and a negative charge is applied to the cathode, the PN junction layer forms an open circuit, so that the cathode and the anode evenly inject carriers into the light emitting layer.
